(19) United States
(12) Patent Application Publication
(10) Pub. No.: US 2024/0389309 A1
(43) Pub. Date: Nov. 21, 2024

(54) MEMORY DEVICE WITH A TRANSISTOR ABOVE VERTICALLY STACKED MEMORY CELLS

(71) Applicant: Micron Technology, Inc., Boise, ID (US)

(72) Inventors: Kamal M. KARDA, Boise, ID (US); Si-Woo LEE, Boise, ID (US); Durai Vishak Nirmal RAMASWAMY, Boise, ID (US); Alessandro CALDERONI, Boise, ID (US); Mark L. FISCHER, Boise, ID (US)

(21) Appl. No.: 18/658,235

(22) Filed: May 8, 2024

Related U.S. Application Data
(60) Provisional application No. 63/502,733, filed on May 17, 2023.

(51) Int. Cl. H10B 12/00; G11C 11/404; H01L 29/417; H10B 80/00

(52) U.S. Cl. CPC H10B 12/50; G11C 11/4045; H01L 29/41775; H10B 80/00

(57) ABSTRACT

Implementations described herein relate to various structures, integrated assemblies, and memory devices. In some implementations, a memory device may include a memory array that includes multiple stacks of vertically stacked memory cells. The memory device may include a transistor positioned above a stack of vertically stacked memory cells of the multiple stacks of vertically stacked memory cells. The transistor may include a channel positioned above the stack of vertically stacked memory cells, a first source/drain region on top of a first portion of the channel, a second source/drain region on top of a second portion of the channel, a gate having a top surface that is lower than a top surface of the first source/drain region and that is lower than a top surface of the second source/drain region, and a gate dielectric that separates the gate from the channel.

### CROSS-REFERENCE TO RELATED APPLICATION

This patent application claims priority to U.S. Provisional Patent Application No. 63/502,733, filed on May 17, 2023, entitled “MEMORY DEVICE WITH A TRANSISTOR ABOVE VERTICALLY STACKED MEMORY CELLS,” and assigned to the assignee hereof. The disclosure of the prior Application is considered part of and is incorporated by reference into this patent application.

### TECHNICAL FIELD

The present disclosure generally relates to semiconductor devices and methods of forming semiconductor devices. For example, the present disclosure relates to a memory device with a transistor above vertically stacked memory cells.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 shows a diagrammatic cross-sectional view of an example structure having a transistor above vertically stacked memory cells.

FIG. 2 shows diagrammatic cross-sectional views of the example structure of FIG. 1 along the line A-A shown in FIG. 1.

FIG. 3 is a flowchart of an example method of forming an integrated assembly or memory device having a transistor above vertically stacked memory cells.

FIG. 4 is a diagrammatic view of a first example process for formation of the structure.

FIG. 5 is a diagrammatic view of a second example process for formation of the structure.

### DETAILED DESCRIPTION

Three-dimensional (3D) memory, such as 3D DRAM, is a type of memory organized into a stack of memory cells arranged in a 3D grid. In 3D DRAM, for example, each memory cell includes a storage capacitor and a transistor that acts as a switch, allowing a memory cell to store a data state (e.g., a 1 or a 0). In 3D memory, a memory device includes multiple stacks (or columns) of memory, and each stack includes a group of memory cells that are stacked vertically on one another. A particular memory cell in a stack may be connected to (e.g., via a local digit line and/or a plate line) a memory cell above that particular memory cell in the stack and/or a memory cell below that particular memory cell in the stack.

All of the memory cells in a particular stack may be connected to a local digit line, which may extend vertically through the stack. The local digit line may be used to transfer data to or from the memory cells in a particular stack. The local digit lines of multiple stacks may all be connected to the same global digit line. Each global digit line of the memory device may be connected to a different group of stacks (via a corresponding group of local digit lines) and a different input/output (I/O) component (e.g., a sense amplifier). An I/O component connected to a particular global digit line may be used to read data from or write data to memory cells in the stacks connected to that particular global digit line.

A global digit line may be selectively connected to a local digit line via a selection component, such as a transistor (sometimes called a “stack selection transistor” herein), positioned on top of a stack of vertically stacked memory cells that are connected to the local digit line. For example, when a transistor (or another type of selection component) is activated via a control gate, current may flow through the transistor, and the local digit line may be electrically connected to the global digit line. When the transistor is deactivated via the control gate, current does not flow through the transistor, and the local digit line is electrically isolated from the global digit line. By activating or deactivating different transistors, the memory device can control which stacks of memory cells are read from and written to (in addition to using access lines, also called word lines, of memory cells).

Forming a transistor positioned above a stack of vertically stacked memory cells presents several challenges. For example, heat is applied to dopants in the transistor (e.g., in a channel region and/or a source/drain region of the transistor) to activate those dopants to give the transistor desired electrical properties. If the transistor is formed after the memory array is formed, and heat is applied to the transistor for dopant activation (e.g., using a laser), the memory array can be degraded due to thermal stress (e.g., physical damage and/or degradation of memory cells), dopant diffusion (e.g., to or from memory cells), interfacial defects, and/or oxidation. One option is to apply a low temperature for dopant activation to reduce degradation of the memory array, but this results in a lower quality transistor having a gate dielectric formed using a low temperature, resulting in more defects in the gate dielectric and more electron leakage than if the gate dielectric had been formed at a high temperature.

Implementations described herein improve three-dimensional memory by activating dopants used in the transistor and/or by forming the transistor (or at least part of the transistor that includes activated dopants) before forming the memory array. As a result, the memory array is higher quality (e.g., with less degradation of memory cells) than if the memory array were formed before activation of dopants of the transistor and then exposed to heat used to activate those dopants. Furthermore, if the transistor is formed and/or dopants are activated before forming the memory array, then a higher temperature can be used for dopant activation without risk of damaging memory cells, resulting in a higher quality transistor (e.g., a higher quality gate dielectric with less electron leakage) than if a lower temperature is used for dopant activation. Furthermore, a less expensive and/or less precise thermal application process, such as thermal annealing, can be used and applied to the entire structure rather than using a laser to apply heat to a focused area of the structure (e.g., the transistor), while avoiding other areas of the structure (e.g., the memory array).

Implementations described herein also address challenges introduced by activating dopants used in the transistor and/or by forming the transistor (or at least part of the transistor that includes activated dopants) before forming the memory array. For example, for case of design, manufacture, or other reasons, a transistor positioned on top of a stack of vertically stacked memory cells would typically have a gate that extends above a top surface of the transistor (e.g., above source/drain regions of the transistor), thus resulting in uneven device topography. Such uneven or non-uniform device topography makes it difficult to accurately form (e.g., deposit or grow) and remove (e.g., etch) material for formation of the memory array after formation of the transistor. Implementations described herein enable formation of the transistor (or part of the transistor) and activation of dopants of the transistor prior to formation of the memory array, while also forming the transistor with a substantially planar (e.g., flat) top surface and substantially uniform topography to enable precise formation of the memory array.

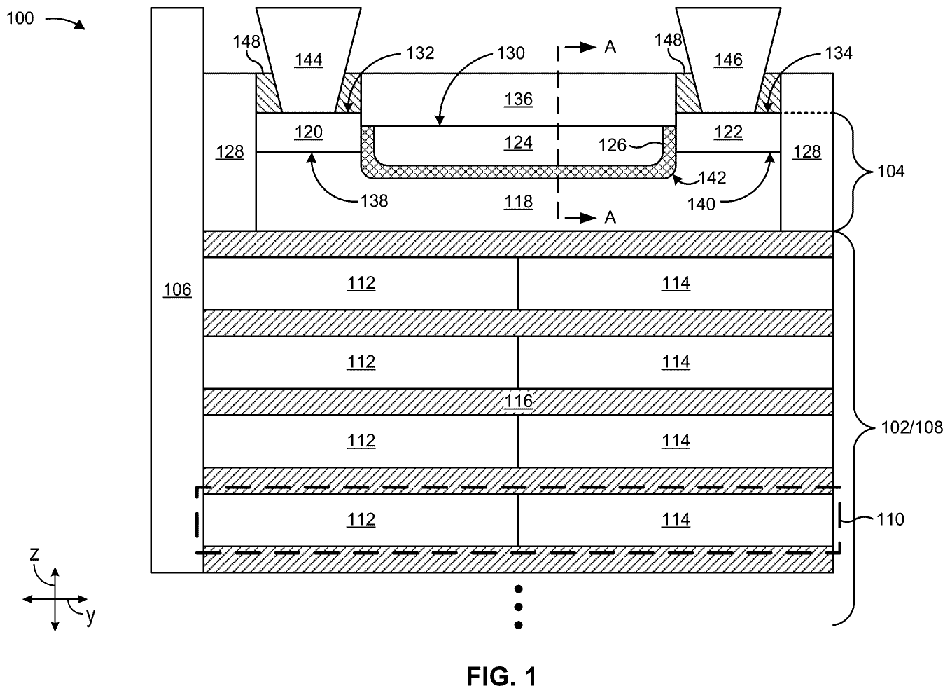

FIG. 1 shows a diagrammatic cross-sectional view of an example structure 100. The structure 100 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller).

As shown in FIG. 1, the structure 100 includes a memory array 102, a stack selection transistor 104, and a local digit line 106. The memory array 102 includes multiple stacks 108 of vertically stacked memory cells 110, represented by a single stack 108 in FIG. 1. All of the memory cells 110 in a single stack 108 may be connected to the same local digit line 106. Furthermore, each stack 108 may have a corresponding local digit line 106 to which memory cells 110 in that stack are connected. A group of local digit lines 106 may be coupled to (e.g., selectively coupled to) the same global digit line (not shown in FIG. 1), as described in more detail elsewhere herein.

As shown, a memory cell 110 may include an access component 112 (e.g., an access transistor) coupled to a storage component 114 (e.g., a capacitor). The access component 112 may control access to the storage component 114 for reading or writing of data via the local digit line 106. The memory cells 110 may be separated from one another via insulative material 116, such as dielectric material. In some implementations, one or more memory cells 110 at the top of the stack 108 may be inoperative memory cells, sometimes called “dummy” memory cells (e.g., the access component 112 may not be coupled to the storage component 114) to prevent parasitic electrical effects between those memory cell(s) and the stack selection transistor 104. The number of dummy memory cells present at the top of the stack 108 may vary. However, in some implementations, the memory cells 110 at the top of the stack 108 are not dummy memory cells (e.g., are operative memory cells).

In some implementations, an insulative separation layer, different from or in addition to the insulative material 116 shown in FIG. 1, is present between the bottom of the stack selection transistor 104 and the top of the memory array 102 (or stack 108). The insulative separation layer may comprise, consist of, or consist essentially of an electrical insulator (e.g., a dielectric material), such as silicon dioxide and/or silicon nitride, among other examples. In some implementations, the insulative separation layer has a height, along the illustrated [symbol] -axis, in a range from approximately 1 nanometer to approximately 30 nanometers to enable desired electrical properties of the stack selection transistor 104, such as to prevent parasitic electrical effects between the memory array 102 and the stack selection transistor 104.

The stack selection transistor 104 may include a channel 118, a first source/drain region 120, a second source/drain region 122, a gate 124, and a gate dielectric 126. The stack selection transistor 104 may be separated from one or more electrical lines, such as the local digit line 106 and/or a plate line (not shown) coupled to the storage components 114 in the stack 108, by one or more isolation regions 128, which may include insulative material (e.g., dielectric material).

As shown, the stack selection transistor 104 may be positioned above the stack 108 of vertically stacked memory cells 110. For example, the channel 118 may be above and/or in contact with the stack 108, such as insulative material 116 of the stack 108. The insulative material 116 may separate the channel 118 from a memory cell 110, which may be an inoperative memory cell in some implementations. Additionally, or alternatively, a distance between the channel 118 and the stack 108 may be smaller than a distance between the first source/drain region 120 and the stack 108, a distance between the second source/drain region 122 and the stack 108, a distance between the gate 124 and the stack 108, and a distance between the gate dielectric 126 and the stack

As shown, the first source/drain region 120 may be on top of a first portion (e.g., a first side) of the channel 118. Similarly, the second source/drain region 122 may be on top of a second portion (e.g., a second side) of the channel 118. As shown, the first source/drain region 120 and/or the second source/drain region 122 may abut (e.g., may be in contact with) the channel 118.

The gate 124 and the gate dielectric 126 may be positioned above a third portion (e.g., a middle) of the channel 118 that is between the first portion and the second portion. As shown, the gate dielectric 126 may separate the gate 124 from the channel 118. For example, the gate dielectric 126 may be on top of and abutting (e.g., in contact with) the channel 118. The gate 124 may abut (e.g., may be in contact with) the gate dielectric 126. In some implementations, the top surface of the first portion of the channel 118 and the top surface of the second portion of the channel 118 are positioned at substantially the same height. In some implementations, the top surface of the first portion of the channel 118 and the top surface of the second portion of the channel 118 are higher than the top surface of the third portion of the channel 118.

In some implementations, the top surface 130 of the gate 124 is not higher than the top surface 132 of the first source/drain region 120. For example, the top surface 130 of the gate 124 may be substantially even with or may be lower than the top surface 132 of the first source/drain region 120. Similarly, in some implementations, the top surface 130 of the gate 124 is not higher than the top surface 134 of the second source/drain region 122. For example, the top surface 130 of the gate 124 may be substantially even with or may be lower than the top surface 134 of the second source/drain region 122. As a result, the stack selection transistor 104 may be formed with a level top surface and/or substantially even topography (e.g., rather having a gate 124 that protrudes above the source/drain regions), which makes it easier to accurately form and remove material for formation of the memory array 102 after formation of the stack selection transistor 104 (or a portion of the stack selection transistor 104). Additionally, or alternatively, the top surface 130 of the gate 124 may be substantially planar (e.g., substantially flat), which also contributes to a substantially even topography. In some implementations, the top surface 130 of the gate 124 may be lower than the top surface 132 of the first source/drain region 120 and/or may be lower than the top surface 134 of the second source/drain region 122. This configuration enables larger electrical contacts (e.g., a first electrical contact 144 and/or a second electrical contact 146, described below) to be formed without those electrical contacts being in contact with or shorting with the gate 124, as compared with a configuration where the top surface 130 of the gate 124 is substantially even with or is above the top surface 132 of the first source/drain region 120 and/or the top surface 134 of the second source/drain region 122.

In some implementations, a dielectric material 136 is on top of the gate 124 in a region between the first source/drain region 120 and the second source/drain region 122. The dielectric material 136 may separate the gate 124 from other electrical components that may be formed on top of the illustrated structure 100. In some implementations, the top surface of the dielectric material 136 may be substantially planar (e.g., substantially flat), which contributes to a substantially even topography.

In FIG. 1, the top surface 130 of the gate 124 is lower than the top surface 132 of the first source/drain region 120 and is higher than the bottom surface of the first source/drain region 120. Furthermore, in FIG. 1, the top surface 130 of the gate 124 is lower than the top surface 134 of the second source/drain region 122 and is higher than the bottom surface of the second source/drain region 122. However, in some implementations, the top surface 130 of the gate 124 is lower than the bottom surface 138 of the first source/drain region 120. Similarly, in some implementations, the top surface 130 of the gate 124 is lower than the bottom surface 140 of the second source/drain region 122.

In some implementations, a top surface of the gate dielectric 126 is substantially level with (e.g., substantially horizontally aligned with) the top surface 130 of the gate 124. Thus, any of the relationships described herein between the top surface 130 of the gate 124 and other components of the structure 100 may also apply to the top surface of the gate dielectric 126.

In some implementations, the gate 124 and/or the gate dielectric 126 may have rounded bottom corners (as opposed to square corners), as shown by reference number 142, due to the manner in which the gate 124 and/or the gate dielectric 126 are formed (e.g., by formation of a trench and subsequent filling of the trench), as described in more detail elsewhere herein. In other words, an area where the bottom surface of the gate 124 (or gate dielectric 126) intersects with a side surface of the gate 124 (or gate dielectric 126) may form an arc or curve rather than an intersection of ninety degrees. This may lower the electrical field present at the corners, which helps to preserve the gate dielectric 126, as opposed to sharp corner that have a higher electrical field and would be more likely to cause breakdown of the gate dielectric 126.

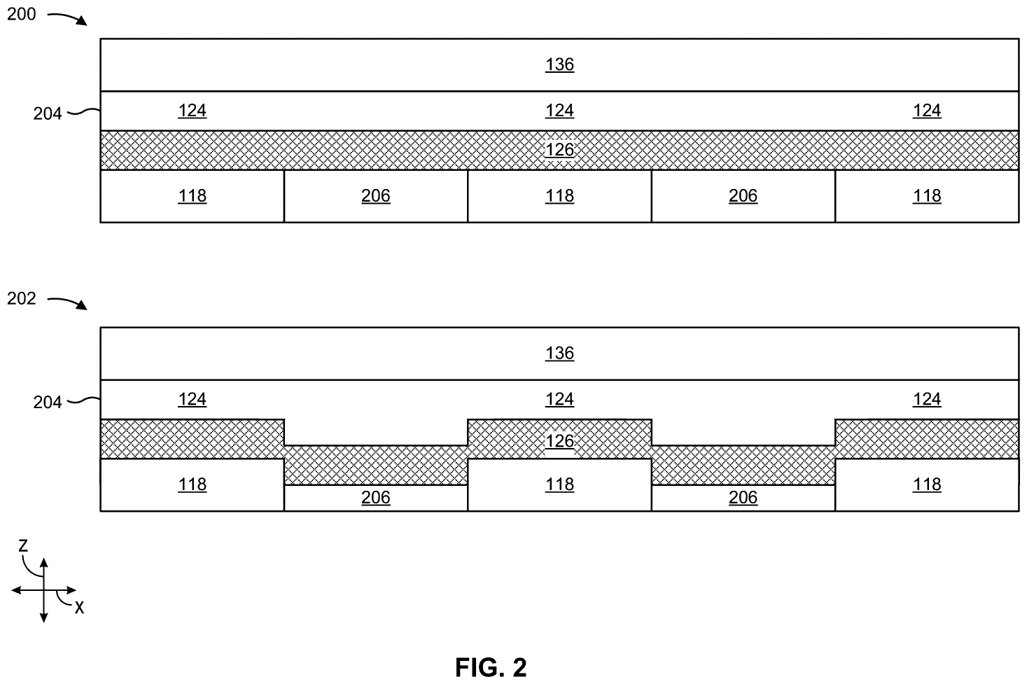

The gate 124 may be part of an access line (sometimes called a word line) that is used to selectively couple a group (e.g., a row) of local digit lines to corresponding global digit lines. The access line may extend through the structure 100 in a direction substantially perpendicular to the illustrated [symbol] -axis and y-axis (e.g., along the x-axis illustrated in FIG. 2). The access line may be positioned above multiple stacks 108 of vertically stacked memory cells 110. A memory device may be configured to apply voltage to or remove voltage from the access line to activate or deactivate gates 124 of stack selection transistors 104 positioned above those stacks 108. Activation of a gate 124 electrically couples a local digit line 106 to a global digit line, and deactivation of the gate 124 electrically isolates the local digit line 106 from the global digit line. Thus, the stack selection transistor 104 may be configured to selectively couple the local digit line 106, which is electrically connected to the stack 108 of vertically stacked memory cells 110, to a global digit line of the memory device. As used herein, electrical connection of the local digit line 106 to the stack 108 means electrical connection of the local digit line 106 to the memory cells 110 in the stack 108.

In some implementations, the access line has a single, substantially planar, bottom surface. In other words, the access line may have a single bottom surface (e.g., including the bottom surface of the gate 124) that is substantially planar. Alternatively, the access line may have a bottom surface that is shallower between the first source/drain region 120 and the second source/drain region 122 (e.g., at the bottom surface of the gate 124) and that is deeper in a region that is not between the first source/drain region 120 and the second source/drain region 122. A substantially planar bottom surface may be easier to manufacture, while a bottom surface that alternates between shallow and deep regions (thus forming a saddle shape over the channel 118) may have better electrical properties (e.g., by mitigating parasitic electrical effects from the memory array 102). Additional details are described in connection with FIG. 2.

As further shown in FIG. 1, the structure 100 may include one or more electrical contacts, shown as a first electrical contact 144 and a second electrical contact 146. For example, the first electrical contact 144 may be on top of and/or in contact with the first source/drain region 120, and the second electrical contact 146 may be on top of and/or in contact with the second source/drain region 122. One of the electrical contacts (e.g., the first electrical contact 144) may be coupled to the local digit line 106, and the other electrical contact (e.g., the second electrical contact 146) may be coupled to the global digit line. In this way, the stack selection transistor 104 selectively couples the local digit line 106 and the global digit line. In some implementations, a dielectric layer 148 may be on top of the first source/drain region 120 and/or the second source/drain region 122. The first electrical contact 144 and the second electrical contact 146 may extend through the dielectric layer 148 to contact the first source/drain region 120 and the second source/drain region 122, respectively.

The local digit line 106, the gate 124, the first electrical contact 144, and/or the second electrical contact 146 may be an electrical conductor and may comprise, consist of, or consist essentially of conductive material, such as a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples.

The insulative material 116, the gate dielectric 126, the isolation region 128, the dielectric material 136, and/or the dielectric layer 148 may be an electrical insulator (e.g., a dielectric material capable of being polarized by an applied electric field, such as via dielectric polarization) and may comprise, consist of, or consist essentially of insulative material and/or dielectric material, such as silicon dioxide and/or silicon nitride, among other examples.

The channel 118 may be a semiconductor and may comprise, consist of, or consist essentially of semiconductive material, such as silicon (e.g., polycrystalline silicon), among other examples. In some implementations, the channel 118 may comprise, consist of, or consist essentially of undoped semiconductor material. Alternatively, the channel 118 may be lightly doped using n-type doping. However, the first source/drain region 120 and/or the second source/drain region 122 may be more heavily doped (e.g., with more electron donor atoms) than the channel 118.

The first source/drain region 120 and/or the second source/drain region 122 (referred to collectively as “source/drain regions”) may be doped semiconductors and may comprise, consist of, or consist essentially of doped semiconductor material, such as n-type doped semiconductor material. The source/drain regions may be n-type doped by incorporating a chemical element or chemical compound that includes electron donor atoms (e.g., phosphorous and/or arsenic) into the semiconductor material (e.g., silicon). In some implementations, the source/drain regions may be heavily doped. Additionally, or alternatively, one or more of the source/drain regions may comprise, consist of, or consist essentially of conductive material other than doped semiconductor material. For example, one or more of the source/drain regions may comprise, consist of, or consist essentially of a metal silicide (e.g., titanium silicide and/or tungsten silicide) and/or other conductive material (e.g., titanium and/or tungsten).

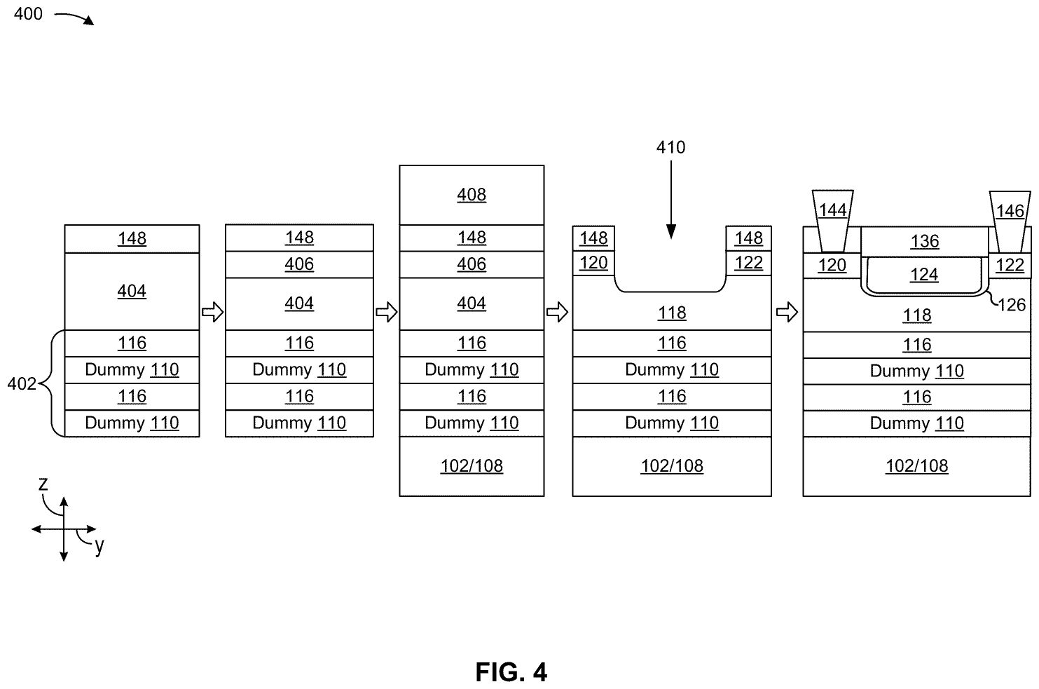

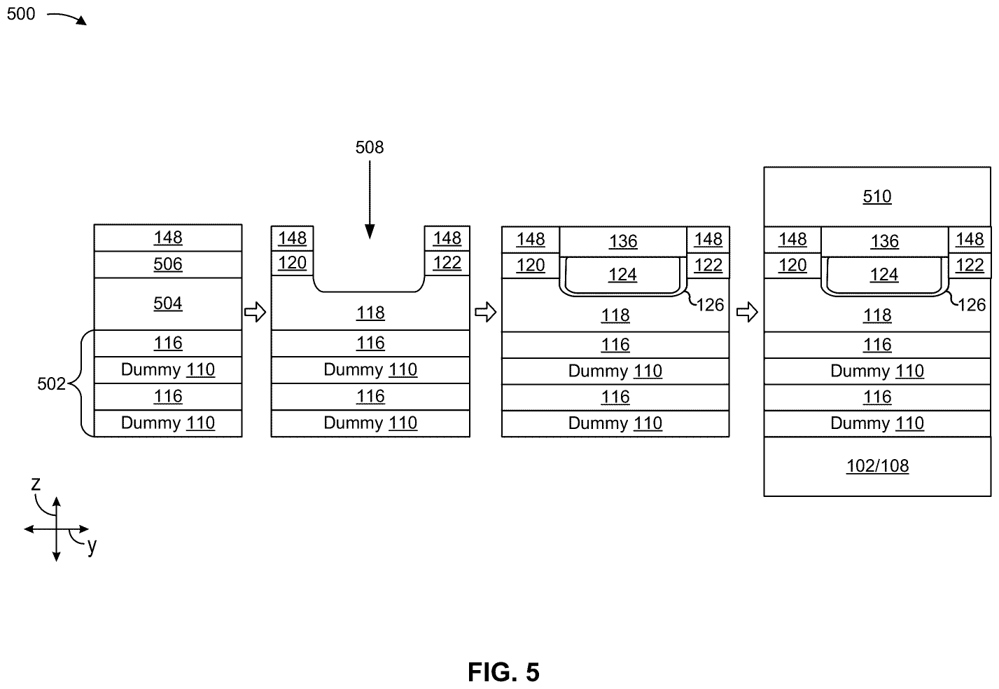

In some implementations, dopant activation for the channel 118 (if the channel 118 is doped), the first source/drain region 120, and/or the second source/drain region 122 may be performed prior to forming the memory array 102. For example, the channel 118, the first source/drain region 120, and/or the second source/drain region 122 may be doped using in situ doping or ion implantation, and heat may be applied to the structure 100 (e.g., via thermal annealing) to activate the dopants in the channel 118, the first source/drain region 120, and/or the second source/drain region 122. The memory array 102 may be formed after applying heat to activate the dopants. Additional details are described in connection with FIGS. 4 and 5.

Because heat is applied to the structure 100 for dopant activation prior to forming the memory array 102, a higher temperature can be used for dopant activation than might otherwise be used if the memory array 102 is formed prior to dopant activation. For example, if the memory array 102 is formed prior to dopant activation, then a lower temperature might be used for dopant activation to prevent or reduce degradation to the memory array 102. Using a higher temperature for dopant activation may result in fewer defects in the stack selection transistor 104, resulting in less leakage from the gate 124 to the channel 118 through the gate dielectric 126. In some implementations, the channel 118, the first source/drain region 120, and/or the second source/drain region 122 may have substantially uniform distribution of dopants (thereby improving operation and reliability of the memory device) because of in situ doping and dopant activation that occur prior to formation of the memory array 102.

Although the stack selection transistor 104 is described in the context of a memory device, in some implementations, the stack selection transistor 104 may be used in a different context. For example, the stack selection transistor 104 may be used in any electronic system that includes multiple stacks of vertically stacked electronic devices (of which memory cells 110 are one example) and for which access to those stacks is to be controlled using stack selection transistors 104. In this case, a separate stack selection transistor 104 may be positioned above each stack of vertically stacked electronic devices to control access to that stack.

In some implementations, the channel 118 has a height, along the illustrated [symbol] -axis, in a range from approximately 10 nanometers to approximately 300 nanometers to enable desired electrical properties of the stack selection transistor 104. In some implementations, a distance between the first source/drain region 120 and the second source/drain region 122, along the illustrated y-axis, is in a range from approximately 50 nanometers to approximately 200 nanometers to enable desired electrical properties of the stack selection transistor 104. In some implementations, the first source/drain region 120 and/or the second source/drain region 122 has a height, along the illustrated [symbol] -axis, in a range from approximately 10 nanometers to approximately 50 nanometers to enable desired electrical properties of the stack selection transistor 104. In some implementations, the gate 124 has a height, along the illustrated [symbol] -axis, in a range from approximately 25 nanometers to approximately 130 nanometers to enable desired electrical properties of the stack selection transistor 104.

Each of the illustrated or described x-axis, y-axis, and [symbol] -axis is substantially perpendicular to the other two axes. In other words, the x-axis is substantially perpendicular to the y-axis and the [symbol] -axis, the y-axis is substantially perpendicular to the x-axis and the [symbol] -axis, and the [symbol] -axis is substantially perpendicular to the x-axis and the y-axis.

The structure 100 may be part of an integrated assembly, such as a memory device or a portion of a memory device. The memory device may include a large quantity of structures 100 and/or memory cells (e.g., hundreds, thousands, millions, or more) that are substantially identical to one another. The structures 100 and/or memory cells may extend across the memory array along the illustrated x-axis (shown in FIG. 2) and the illustrated y-axis to form a three-dimensional grid.

As indicated above, FIG. 1 is provided as an example. Other examples may differ from what is described with respect to FIG. 1.

FIG. 2 shows diagrammatic cross-sectional views 200 and 202 of the example structure 100 along the line A-A shown in FIG. 1. The cross-sectional views of FIG. 2 show multiple channels 118 (of multiple corresponding stack selection transistors 104), multiple gates 124 (of multiple corresponding stack selection transistors 104) along an access line 204, the gate dielectric 126, the dielectric material 136, and multiple dielectric regions 206.

As shown in FIG. 2, the access line 204 (e.g., a material of the gate 124), the gate dielectric 126, and the dielectric material 136 may extend through the structure 100 (e.g., over multiple stacks 108) along the illustrated x-axis, whereas the channels 118 and the dielectric regions 206 alternate along the illustrated x-axis. For example, each channel 118 may be positioned above a corresponding stack 108, and a dielectric region 206 may separate channels 118 that are consecutive (e.g., adjacent but not in contact with one another) to provide electric isolation. The dielectric region 206 may be an electrical insulator (e.g., a dielectric material capable of being polarized by an applied electric field, such as via dielectric polarization) and may comprise, consist of, or consist essentially of insulative material and/or dielectric material, such as silicon dioxide and/or silicon nitride, among other examples.

In the first cross-sectional view 200, the access line 204 has a single, substantially planar, bottom surface. In other words, the access line 204 has a single bottom surface (e.g., including the bottom surfaces of the gates 124) that is substantially planar. This may reduce manufacturing cost (e.g., as compared to the structure 100 shown in the second cross-sectional view 202). In some implementations of this configuration, the gate 124 has a height, along the illustrated [symbol] -axis, in a range from approximately 25 nanometers to approximately 100 nanometers to enable desired electrical properties of the stack selection transistor 104.

In the second cross-sectional view 202, the access line 204 has a bottom surface that is shallower above the channel 118 (e.g., between the first source/drain region 120 and the second source/drain region 122 shown in FIG. 1) and that is deeper in a region that is not above the channel 118 (e.g., a regions that is between consecutive channels 118, and/or a region that is not between the first source/drain region 120 and the second source/drain region 122 shown in FIG. 1). This may enable better electrical operation of stack selection transistors 104 (e.g., as compared to the structure 100 shown in the first cross-sectional view 200). In some implementations of this configuration, the gate 124 has a height, along the illustrated [symbol] -axis and in the shallow region above the channel 118, in a range from approximately 25 nanometers to approximately 100 nanometers to enable desired electrical properties of the stack selection transistor 104. In some implementations of this configuration, the gate 124 has a height, along the illustrated [symbol] -axis and in the deeper region that is not above the channel 118, in a range from approximately 30 nanometers to approximately 130 nanometers to enable desired electrical properties of the stack selection transistor 104.

As indicated above, FIG. 2 is provided as an example. Other examples may differ from what is described with respect to FIG. 2.

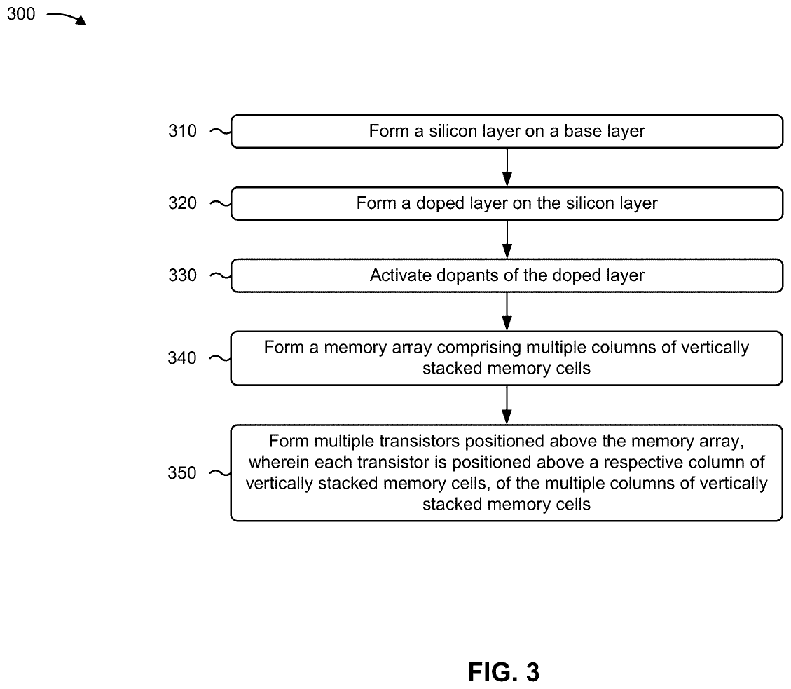

FIG. 3 is a flowchart of an example method 300 of forming an integrated assembly or memory device having a transistor above vertically stacked memory cells. In some implementations, one or more process blocks of FIG. 3 may be performed by various semiconductor manufacturing equipment.

As shown in FIG. 3, the method 300 may include forming a silicon layer on a base layer (block 310). As further shown in FIG. 3, the method 300 may include forming a doped layer on the silicon layer (block 320). As further shown in FIG. 3, the method 300 may include activating dopants of the doped layer (block 330). As further shown in FIG. 3, the method 300 may include forming a memory array comprising multiple stacks of vertically stacked memory cells (block 340). As further shown in FIG. 3, the method 300 may include forming multiple transistors positioned above the memory array, wherein each transistor is positioned above a respective stack of vertically stacked memory cells, of the multiple stacks of vertically stacked memory cells (block 350).

The method 300 may include additional aspects, such as any single aspect or any combination of aspects described below and/or in connection with one or more other methods described elsewhere herein.

In a first aspect, the transistor includes a channel positioned on top of the

respective stack of vertically stacked memory cells, a first source/drain region on top of a first portion of the channel, a second source/drain region on top of a second portion of the channel, a gate having a top surface that is lower than a top surface of the first source/drain region and that is lower than a top surface of the second source/drain region, and a gate dielectric that separates the gate from the channel.

In a second aspect, alone or in combination with the first aspect, the memory array and the multiple transistors are formed after activating the dopants of the doped layer.

In a third aspect, alone or in combination with one or more of the first and second aspects, the multiple transistors are formed before the memory array is formed.

In a fourth aspect, alone or in combination with one or more of the first and second aspects, the multiple transistors are formed after the memory array is formed.

In a fifth aspect, alone or in combination with one or more of the first through fourth aspects, the method 300 includes forming the gate as part of an access line having a single bottom surface that is substantially planar.

In a sixth aspect, alone or in combination with one or more of the first through fourth aspects, the method 300 includes forming the gate as part of an access line having a bottom surface that is shallower between the first source/drain region and the second source/drain region and that is deeper in a region that is not between the first source/drain region and the second source/drain region.

In a seventh aspect, alone or in combination with one or more of the first through sixth aspects, the method 300 includes forming a local digit line that is electrically connected to the respective stack of vertically stacked memory cells, forming a global digit line, coupling the local digit line and the first source/drain region, and coupling the global digit line and the second source/drain region.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the structure 100, an integrated assembly that includes the structure 100, any part described herein of the structure 100, and/or any part described herein of an integrated assembly that includes the structure 100.

FIG. 4 is a diagrammatic view of a first example process 400 for formation of the structure 100. As shown in FIG. 4, the process 400 may include forming (e.g., depositing or growing) a base layer 402. In some implementations, the base layer 402 is formed on a substrate. Alternatively, the base layer 402 may be a substrate. In the example process 400 of FIG. 4, the base layer includes one or more dummy memory cells 110 and insulative material 116.

As further shown, the process 400 may include forming a silicon layer 404 on the base layer 402. The silicon layer 404 may be undoped or may be lightly doped (e.g., with boron), as described above in connection with the channel 118, and may eventually form the channel 118 (e.g., after the process 400 is performed). As further shown, the process 400 may include forming the dielectric layer 148 on top of the silicon layer 404.

As further shown, the process 400 may include forming a doped layer 406 on the silicon layer 404. In some implementations, the doped layer 406 may be formed by ion implantation in a portion of the silicon layer 404, as shown in FIG. 4. Alternatively, the doped layer 406 may be formed using in situ doping, such that the doped layer 406 is doped as the material of the doped layer 406 is being formed (e.g., grown or deposited). In this case, the process 400 may include forming the dielectric layer 148 on top of the doped layer 406.

The doped layer 406 may eventually form the first source/drain region 120 and the second source/drain region 122 (e.g., after the process 400 is performed) and may comprise, consist of, or consist essentially of any of the materials of the first source/drain region 120 and the second source/drain region described above in connection with FIG. 1. The process 400 may include activating dopants (e.g., n-type dopants) of the doped layer 406. For example, heat may be applied to activate the dopants, such as by using thermal annealing (e.g., rapid thermal annealing). Notably, dopant activation is performed before forming the memory array 102.

As further shown, the process 400 may include forming a mask 408 (e.g., a hard mask) on top of the dielectric layer 148. After the mask 408 is formed, the process 400 may include forming a stack 108 of the memory array 102 below the base layer 402. Although FIG. 4 shows formation of a single stack 108 and structures on top of that single stack 108, the process 400 may include forming a structure that includes multiple stacks 108 (e.g., extending in the y-direction along the illustrated cross-section and along the x-direction shown in FIG. 2). The multiple stacks 108 may from an entire memory array 102. Thus, the memory array 102 may be formed after activating dopants of the doped layer 406 (and/or after activating dopants of the channel 118), which has advantages described elsewhere herein.

As further shown, the process 400 may include removing (e.g., etching) a portion of the dielectric layer 148, a portion of the doped layer 406, and a portion of the silicon layer 404 (e.g., material of the channel 118) to form a trench 410. The trench 410 may be formed completely through the dielectric layer 148 and through the doped layer 406, which forms the first source/drain region 120 and the second source/drain region 122. The trench may 410 be formed partially through the silicon layer 404 to form the channel 118 having the illustrated shape, with a top surface of a first portion of the channel 118 (e.g., below the first source/drain region 120) and a top surface of a second portion of the channel 118 (e.g., below the second source/drain region 122) being higher than a top surface of a third portion of the channel 118 (e.g., between the first source/drain region 120 and the second source/drain region 122). In some implementations, one or more masks may be used to form the trench 410. For example, one or more masks (e.g., the mask 408) may be deposited and/or patterned on the dielectric layer 148 prior to removing material to form the trench 410. The one or more masks may be subsequently removed.

As further shown, the process 400 may include forming the gate dielectric 126 in the trench 410, such that the gate dielectric 126 is formed on the channel 118 between the first source/drain region 120 and the second source/drain region 122 (and in contact with the first source/drain region 120 and the second source/drain region 122). The gate dielectric 126 may be formed with a substantially level bottom surface abutting multiple channels 118 and multiple dielectric regions 206 (where a dielectric region 206 is between two channels 118), as described above in connection with the first cross-sectional view 200 of FIG. 2. Alternatively, the gate dielectric 126 may have a bottom surface that is shallower above the channels 118 and that is deeper between channels 118 (e.g., above dielectric regions 206), as described above in connection with the second cross-sectional view 202 of FIG. 2. In this case, dielectric material of the dielectric regions 206 may be removed (e.g., to a deeper depth than the channel 118) prior to forming the gate dielectric 126.

As further shown, the process 400 may include forming the gate 124 in the trench 410 on top of the gate dielectric 126. In some implementations, the process 400 may include planarizing the top surface of the gate 124, such as by using chemical-mechanical polishing or another suitable planarization technique. This may result in a gate 124 having a substantially level, planar, or flat top surface for more uniform topography.

As further shown, the process 400 may include forming the dielectric material 136 in the trench 410 on top of the gate 124 and the gate dielectric 126. In some implementations, the process 400 may include planarizing the top surface of the dielectric material 136 and the dielectric layer 148, such as by using chemical-mechanical polishing or another suitable planarization technique, for more uniform topography.

As further shown, the process 400 may include forming the first electrical contact 144 through the dielectric layer 148 and in contact with the first source/drain region 120 and forming the second electrical contact 146 through the dielectric layer 148 and in contact with the second source/drain region 122. For example, a portion of the dielectric layer 148 may be removed (e.g., using masking and/or patterning) through the entire dielectric layer 148 to form a first gap that exposes the first source/drain region 120 and a second gap that exposes the second source/drain region 122. The first electrical contact 144 may be formed in the first gap, and the second electrical contact 146 may be formed in the second gap.

In some implementations, the process 400 may include forming a local digit line 106 that is electrically connected to the stack 108 of vertically stacked memory cells 110, forming a global digit line, coupling the local digit line 106 and the first source/drain region 120 (e.g., via the first electrical contact 144), and coupling the global digit line and the second source/drain region 122 (e.g., via the second electrical contact 146). In this way, the stack 108 can be selected or deselected for reading or writing of data to memory cells in the stack 108.

In the example process 400 of FIG. 4, the memory array 102 and transistors 104 are formed after activating the dopants of the doped layer 406. Furthermore, the transistors 104 are formed after the memory array 102 is formed. However, in some implementations, the transistors 104 are formed before the memory array 102 is formed, as described below in connection with FIG. 5.

As indicated above, FIG. 4 is provided as an example. Other examples may differ from what is described with respect to FIG. 4.

FIG. 5 is a diagrammatic view of a second example process 500 for formation of the structure 100. As shown in FIG. 5, the process 500 may include forming (e.g., depositing or growing) a base layer 502, forming a silicon layer 504 on the base layer 502, and forming a doped layer 506 on the silicon layer 504, and forming the dielectric layer 148 on the doped layer 506, as described above in connection with FIG. 4. The process 400 may include activating dopants (e.g., n-type dopants) of the doped layer 406. For example, heat may be applied to activate the dopants, such as by using thermal annealing (e.g., rapid thermal annealing). Notably, dopant activation is performed before forming the memory array 102.

As further shown, the process 500 may include forming a trench 508, forming the gate dielectric 126 in the trench 508, forming the gate 124 in the trench 508 on top of the gate dielectric 126, and forming the dielectric material 136 in the trench 508 on top of the gate 124 and the gate dielectric 126, as described above in connection with FIG. 4 (except that in the process 500, the transistor 104 is formed prior to forming the memory array 102). As also described above in connection with FIG. 4, the gate dielectric 126 may be formed to have a shape shown in the first cross-sectional view 200 of FIG. 2 or may be formed to have a shape shown in the second cross-sectional view 202 of FIG. 2.

As further shown, the process 500 may include forming a mask 510 (e.g., a hard mask) on top of the dielectric layer 148 (and the dielectric material 136), in a similar manner as described above in connection with FIG. 4. After the mask 510 is formed, the process 500 may include forming a stack 108 of the memory array 102 (and the entire memory array 102) below the base layer 502, as described above in connection with FIG. 5. Thus, the memory array 102 may be formed after activating dopants of the doped layer 406 (and/or after activating dopants of the channel 118), which has advantages described elsewhere herein.

Although not shown in FIG. 5, the process 500 may include removing the mask 510, forming the first electrical contact 144, forming the second electrical contact 146, forming a local digit line 106, forming a global digit line, coupling the local digit line 106 and the first source/drain region 120, and coupling the global digit line and the second source/drain region 122, as described above in connection with FIG. 4.

In the example process 500 of FIG. 5, the memory array 102 and transistors 104 are formed after activating the dopants of the doped layer 506. Furthermore, the transistors 104 are formed before the memory array 102 is formed.

As indicated above, FIG. 5 is provided as an example. Other examples may differ from what is described with respect to FIG. 5.

The example process steps described in connection with FIG. 4 and FIG. 5 may correspond to the method 300 of FIG. 3 and/or one or more blocks of the method 300 of FIG. 3. However, the processes described in connection with FIG. 4 and FIG. 5 are examples, and other example processes may be used to form the structure 100, an integrated assembly that includes the structure 100, and/or one or more parts of the structure 100 and/or the integrated assembly. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

In some implementations, a memory device includes a memory array comprising multiple stacks of vertically stacked memory cells; and a transistor positioned above a stack of vertically stacked memory cells of the multiple stacks of vertically stacked memory cells, wherein the transistor comprises: a channel positioned above the stack of vertically stacked memory cells; a first source/drain region on top of a first portion of the channel; a second source/drain region on top of a second portion of the channel; a gate having a top surface that is lower than a top surface of the first source/drain region and that is lower than a top surface of the second source/drain region; and a gate dielectric that separates the gate from the channel.

In some implementations, an integrated assembly includes multiple stacks of vertically stacked electronic devices; and a transistor positioned above a stack of vertically stacked electronic devices of the multiple stacks of vertically stacked electronic devices, wherein the transistor comprises: a channel positioned on top of the stack of vertically stacked electronic devices; a first source/drain region on top of a first portion of the channel; a second source/drain region on top of a second portion of the channel; a gate that is part of an access line running through the integrated assembly, wherein a top surface of the gate is lower than a top surface of the first source/drain region and is lower than a top surface of the second source/drain region; and a gate dielectric that separates the gate from the channel.

In some implementations, a method includes forming a silicon layer on a base layer; forming a doped layer on the silicon layer; activating dopants of the doped layer; forming a memory array comprising multiple stacks of vertically stacked memory cells; and forming multiple transistors positioned above the memory array, wherein each transistor is positioned above a respective stack of vertically stacked memory cells, of the multiple stacks of vertically stacked memory cells, and comprises: a channel positioned on top of the respective stack of vertically stacked memory cells; a first source/drain region on top of a first portion of the channel; a second source/drain region on top of a second portion of the channel; a gate having a top surface that is lower than a top surface of the first source/drain region and that is lower than a top surface of the second source/drain region; and a gate dielectric that separates the gate from the channel.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for case of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
a memory array comprising multiple stacks of vertically stacked memory cells; and
a transistor positioned above a stack of vertically stacked memory cells of the multiple stacks of vertically stacked memory cells,
wherein the transistor comprises:
a channel positioned above the stack of vertically stacked memory cells;
a first source/drain region on top of a first portion of the channel;
a second source/drain region on top of a second portion of the channel;
a gate having a top surface that is lower than a top surface of the first source/drain region and that is lower than a top surface of the second source/drain region; and
a gate dielectric that separates the gate from the channel.

2. The memory device of claim 1, wherein the transistor is configured to selectively couple a local digit line, electrically connected to the stack of vertically stacked memory cells, to a global digit line of the memory device.

3. The memory device of claim 2, wherein the global digit line is selectively coupled to multiple local digit lines, and
wherein each local digit line, of the multiple local digit lines, is electrically connected to a different stack of vertically stacked memory cells of the multiple stacks of vertically stacked memory cells.

4. The memory device of claim 1, wherein the top surface of the gate is lower than a bottom surface of the first source/drain region and is lower than a bottom surface of the second source/drain region.

5. The memory device of claim 1, wherein the top surface of the gate is substantially planar.

6. The memory device of claim 1, further comprising a dielectric material on top of the gate and between the first source/drain region and the second source/drain region.

7. The memory device of claim 1, wherein the gate is part of an access line having a single bottom surface that is substantially planar.

8. The memory device of claim 1, wherein the gate is part of an access line having a bottom surface that is shallower between the first source/drain region and the second source/drain region and that is deeper in a region that is not between the first source/drain region and the second source/drain region.

9. The memory device of claim 1, wherein dopant activation for at least one of the channel, the first source/drain region, or the second source/drain region is performed prior to forming the memory array.

10. An integrated assembly, comprising:
multiple stacks of vertically stacked electronic devices; and
a transistor positioned above a stack of vertically stacked electronic devices of the multiple stacks of vertically stacked electronic devices,
wherein the transistor comprises:
a channel positioned on top of the stack of vertically stacked electronic devices;
a first source/drain region on top of a first portion of the channel;
a second source/drain region on top of a second portion of the channel;
a gate that is part of an access line running through the integrated assembly, wherein a top surface of the gate is lower than a top surface of the first source/drain region and is lower than a top surface of the second source/drain region; and
a gate dielectric that separates the gate from the channel.

11. The integrated assembly of claim 10, wherein the top surface of the gate is lower than a bottom surface of the first source/drain region and is lower than a bottom surface of the second source/drain region.

12. The integrated assembly of claim 10, wherein the top surface of the gate is substantially planar.

13. The integrated assembly of claim 10, wherein the access line has a single bottom surface that is substantially planar.

14. The integrated assembly of claim 10, wherein the access line has a bottom surface that is shallower above the channel and that is deeper in a region that is between the channel and consecutive channel.

15. A method, comprising:
forming a silicon layer on a base layer;
forming a doped layer on the silicon layer;
activating dopants of the doped layer;
forming a memory array comprising multiple stacks of vertically stacked memory cells; and
forming multiple transistors positioned above the memory array,
wherein each transistor is positioned above a respective stack of vertically stacked memory cells, of the multiple stacks of vertically stacked memory cells, and comprises:
a channel positioned on top of the respective stack of vertically stacked memory cells;
a first source/drain region on top of a first portion of the channel;
a second source/drain region on top of a second portion of the channel;
a gate having a top surface that is lower than a top surface of the first source/drain region and that is lower than a top surface of the second source/drain region; and
a gate dielectric that separates the gate from the channel.

16. The method of claim 15, wherein the memory array and the multiple transistors are formed after activating the dopants of the doped layer.

17. The method of claim 15, wherein the multiple transistors are formed before the memory array is formed.

18. The method of claim 15, wherein the multiple transistors are formed after the memory array is formed.

19. The method of claim 15, further comprising forming the gate as part of an access line having one of:
a single bottom surface that is substantially planar, or
a bottom surface that is shallower between the first source/drain region and the second source/drain region and that is deeper in a region that is not between the first source/drain region and the second source/drain region.

20. The method of claim 15, further comprising:
forming a local digit line that is electrically connected to the respective stack of vertically stacked memory cells;
forming a global digit line;
coupling the local digit line and the first source/drain region; and
coupling the global digit line and the second source/drain region.
